(19) United States
(12) Patent Application Publication
(10) Pub. No.: US 2020/0216959 A1
(43) Pub. Date: Jul. 9, 2020

(54) HIGH ASPECT RATIO DEPOSITION

(71) Applicant: Applied Materials, Inc., Santa Clara, CA (US)

(72) Inventors: Shaunak MUKHERJEE, San Jose, CA (US); Abhijit B. MALLICK, Fremont, CA (US)

(73) Assignee: Applied Materials, Inc., Santa Clara, CA (US)

(21) Appl. No.: 16/648,209

(22) PCT Filed: Aug. 20, 2018
(86) PCT No.: PCT/US2018/047067

§ 371 Date: Mar. 17, 2020

Related U.S. Application Data
(60) Provisional application No. 62/561,336, filed on Sep. 21, 2017.

(51) Int. Cl. C23C 16/505; H01L 45/00; H01L 21/02; H01J 37/32; C23C 16/34; C23C 16/04; C23C 16/52

(52) U.S. Cl. CPC C23C 16/505; H01L 45/16; H01L 45/12; H01L 21/0217; H01L 21/02274; H01J 37/32146; H01J 2237/3323; C23C 16/045; C23C 16/52; H01L 45/06; H01L 45/144; H01J 2237/3321; H01J 2237/3327; C23C 16/345

(57) ABSTRACT

Embodiments of the present disclosure generally relate to methods of depositing a conformal layer on surfaces of high aspect ratio structures and related apparatuses for performing these methods. The conformal layers described herein are formed using PECVD methods in which a semiconductor device including a plurality of high aspect ratio features is disposed on a substrate support in a process volume of a process chamber, gases are supplied to the process volume, and a plasma is generated in the process volume by pulsing RF power coupled to the process gases disposed in the process volume of the process chamber.

### BACKGROUND

### Field

Embodiments of the present disclosure generally relate to methods of depositing a layer on surfaces of high aspect ratio structures and related apparatuses for performing these methods.

### Description of the Related Art

Semiconductor processing may involve filling or coating high aspect ratio structures, such as trenches formed on semiconductor devices. Used herein, a high aspect ratio structure refers to a structure having an aspect ratio greater than 4:1. As widths of these structures (e.g., trench width) become narrower and the aspect ratios increase, the process of filling or coating these structures becomes more challenging, especially when attempting to deposit a uniform layer, such as a conformal liner, over the high aspect ratio structures. For example, conformal liners of dielectric materials (e.g., silicon nitride) are often used to coat trenches adjacent to memory cell units, such as phase-change memory cell units, that can have an aspect ratio greater than 4:1 or even greater than 15:1. Plasma-enhanced chemical vapor deposition (PECVD) is often used to deposit conformal liners, such as silicon nitride liners, in trenches having an aspect ratio of 3:1 or less. However, overhang and poor step coverage increasingly becomes a problem when the aspect ratio of the structure is around 3:1 or greater.

FIG. 1A illustrates a cross-sectional view of a semiconductor device 50 including a dielectric layer 61 formed over a plurality of high aspect ratio features, which include a plurality of trenches 51 using a conventional PECVD method. The semiconductor device 50 illustrated in FIG. 1A includes the trenches 51 and a corresponding plurality of dividing structures 54 formed on a substrate 40. The dividing structures 54 separate the trenches 51 from each other.

The trenches 51 each include a bottom 52 and one or more sidewalls 53 that also form sidewalls of the dividing structures 54. The dielectric layer 61 is formed over the trenches 51 and dividing structures 54 using a PECVD process. The dielectric layer 61 includes a bottom portion 62 formed on the bottom 52 of the trench 51, sidewall portions 63 formed on the sidewalls 53 of the trench 51, and an upper portion 64 formed on top of the dividing structures 54. A conventional PECVD process typically deposits more material of the dielectric layer 61 on top of the dividing structures 54 and on the upper portions of the sidewalls 53 than on the bottom 52 of the trenches 51 or on lower portions of the sidewalls 53. This uneven deposition results in poor step coverage with the dielectric layer 61 having a thickness 66 at the top of the dividing structures 54 that is much greater than a thickness 67 of the dielectric layer 61 at the bottom of the trenches 51. This uneven deposition also results in overhangs 65 in the upper portions 64 of the dielectric layer 61, which can prevent additional material of the dielectric layer 61 from being deposited in the trenches 51 when neighboring overhangs 65 meet each other. Even when neighboring overhangs 65 do not meet each other, the increased deposition at the top of the dividing structures 54 and upper portions of the sidewalls 53 slows the deposition at the lower portions of the sidewalls 53 and at the bottom 52 of the trench 51.

Other methods, such as atomic layer deposition (ALD) and thermal chemical vapor deposition (CVD), can sometimes be used to form uniform layers (e.g., conformal liners) over high aspect ratio structures, such as trenches, but ALD and thermal CVD utilize temperatures greater than 400° C. to form a high-quality film. However, temperatures greater than 400° C. generally cannot be used during the fabrication of phase change memory cells, which utilizes temperatures of 300° C. or less due to thermal budgeting concerns. Furthermore, processes, such as ALD, deposit layers at a much slower rate than PECVD processes, increasing production costs for these devices due to lower throughput. Therefore, there is a need for an improved method and apparatus for forming layers over high aspect ratio structures at temperatures of 300° C. or less.

### SUMMARY OF THE INVENTION

Embodiments of the present disclosure generally relate to methods of depositing a conformal layer (e.g., a dielectric layer) on surfaces of high aspect ratio structures and related apparatuses for performing these methods. In one embodiment, a method of forming a layer on a substrate is provided. The method includes supplying a first gas and a second gas to a process volume of a plasma chamber, wherein a substrate is disposed on a substrate support in the process volume and the substrate includes a plurality of high aspect ratio structures having an aspect ratio of at least 4:1, and depositing a first portion of a layer by generating a first plasma of the first gas and the second gas within the process volume by energizing an RF power source coupled to the plasma chamber at a first pulse frequency, wherein the first pulse frequency is from about 1 kHz to about 100 kHz, and the first pulse frequency has a duty cycle from about 10% to about 50%.

In another embodiment, a method of forming a dielectric layer on a substrate is provided. The method includes supplying a first gas comprising silicon and a second gas comprising nitrogen to a process volume of a plasma chamber, wherein a substrate is disposed on a substrate support in the process volume and the substrate includes a plurality of high aspect ratio structures having an aspect ratio of at least 4:1, and depositing a first portion of a dielectric layer by generating a first plasma of the first gas and the second gas within the process volume by energizing an RF power source coupled to the plasma chamber at a first pulse frequency, wherein the first pulse frequency is from about 1 kHz to about 100 kHz, and the first pulse frequency has a duty cycle from about 10% to about 50%.

In another embodiment, a method of encapsulating a phase change memory cell unit with a dielectric layer is provided. The method includes supplying a first gas comprising silicon and a second gas comprising nitrogen to a process volume of a plasma chamber, wherein a substrate is disposed on a substrate support in the process volume and the substrate includes a plurality of phase change memory cell units separated by trenches that have an aspect ratio of at least 4:1, and depositing a first portion of a dielectric layer by generating a first plasma of the first gas and the second gas within the process volume by energizing an RF power source coupled to the plasma chamber at a first pulse frequency, wherein the first pulse frequency is from about 1 kHz to about 100 kHz, the first pulse frequency has a duty cycle from about 10% to about 50%, a temperature of the process volume during the depositing the first portion is less than 300° C., and a pressure in the process volume during the depositing the first portion is from about 8 Tarr to about 30 Torr.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of scope, for the disclosure may admit to other equally effective embodiments.

FIG. 1A illustrates a cross-sectional view of a semiconductor device including a dielectric layer formed over a plurality of high aspect ratio features using a conventional method.

FIG. 1B illustrates a cross-sectional view of a semiconductor device including a dielectric layer formed over a plurality of high aspect ratio features, according to one embodiment.

FIG. 1C is a close-up of a section of the dielectric layer shown in FIG. 1B, according to one embodiment.

FIG. 2 is a cross sectional view of a PECVD apparatus that can be used to form the dielectric layer of FIG. 1B, according to one embodiment.

FIG. 3 is a process flow diagram of a method of forming the dielectric layer on the substrate of FIG. 1B using the PECVD apparatus of FIG. 2, according to one embodiment.

FIG. 4 is a schematic diagram of an RF power pulse train that can be used in the PECVD apparatus of FIG. 2, according to one embodiment.

To facilitate understanding, identical reference numerals have been used, where possible, to designate identical elements that are common to the figures. It is contemplated that elements disclosed in one embodiment may be beneficially utilized on other embodiments without specific recitation. The drawings referred to here should not be understood as being drawn to scale unless specifically noted. Also, the drawings are often simplified and details or components omitted for clarity of presentation and explanation. The drawings and discussion serve to explain principles discussed below, where like designations denote like elements.

### DETAILED DESCRIPTION

Embodiments of the present disclosure generally relate to methods of depositing a conformal layer (e.g., a dielectric layer) on surfaces of high aspect ratio structures and related apparatuses for performing these methods. The conformal layers described herein are formed using PECVD methods in which a semiconductor device including a plurality of high aspect ratio features is disposed on a substrate support in a process volume of a process chamber, gases are supplied to the process volume, and a plasma is generated in the process volume by pulsing RF power coupled to the process gases disposed in the process volume of the process chamber. Pulsing the RF power coupled to the process chamber has the effect of increasing the ratio of radicals produced relative to ions produced in the plasma when compared to applying continuous RF power to the process chamber. Because radicals formed in a plasma are generally less reactive than ions formed in the plasma and are not attracted to the more highly charged regions of the high aspect ratio features (e.g., top corners of the high aspect ratio features such as dividing structures 54), the plasma-formed reactants created by pulsed RF power have a higher likelihood of reaching the lower regions of the high aspect ratio structures (e.g., bottom of a trench) than the plasma-formed reactants created by use of a continuously applied RF power. Such processing leads to a more uniform deposition on the high aspect ratio structures. Although the following disclosure describes methods of depositing one or more dielectric layers, the disclosure is equally applicable to depositing other types of layers suitable for PECVD processes besides dielectric layers.

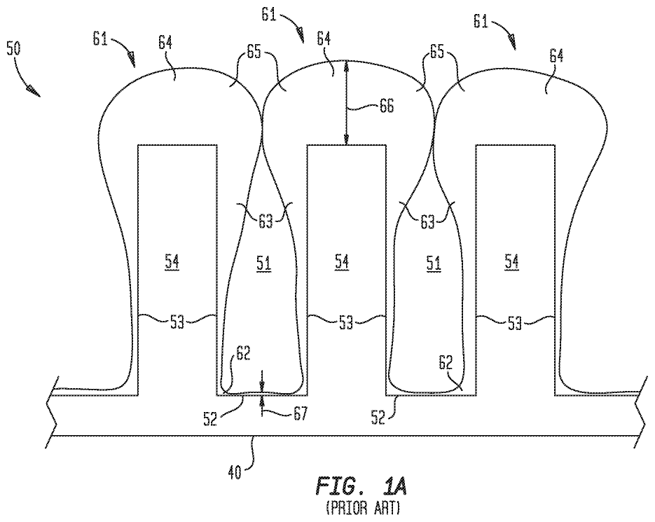

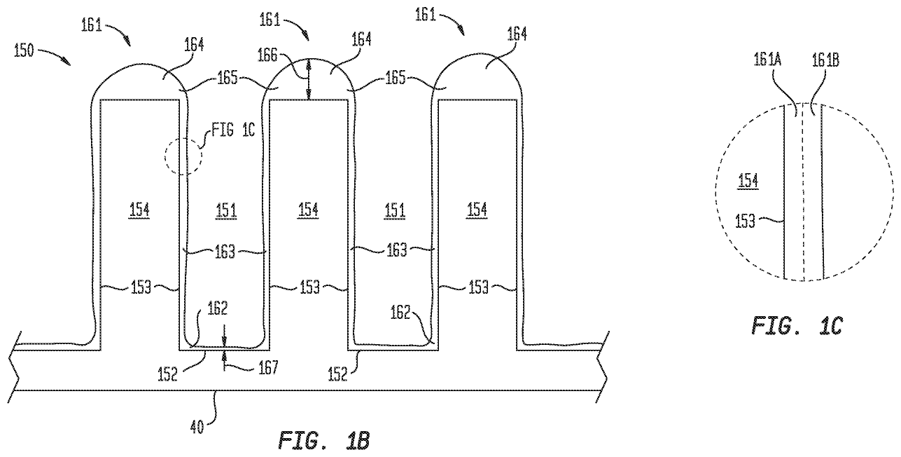

FIG. 1B illustrates a cross-sectional view of a semiconductor device 150 including a dielectric layer 161 formed over a plurality of high aspect ratio features, such as trenches 151, according to one embodiment. The semiconductor device 150 includes a plurality of trenches 151 and a corresponding plurality of dividing structures 154 that are similar to the trenches 51 and dividing structures 54 described in FIG. 1A above. The trenches 151 each include a bottom 152 and one or more sidewalls 153 that also form sidewalls of the dividing structures 154. Furthermore, the dielectric layer 161 of FIG. 1B is different from the dielectric layer 61 of FIG. 1A. The dielectric layer 161 of FIG. 1B has a significantly higher degree of thickness uniformity relative to the dielectric layer 61 of FIG. 1A. For example, the step coverage is significantly improved with the difference between a thickness 167 of the dielectric layer 161 at the top of the dividing structures 154 relative to a thickness 166 of the dielectric layer 161 at the bottom of the trenches 151 being much smaller than the difference between the corresponding thicknesses 66, 67 of the dielectric layer 61 in the semiconductor device 50 of FIG. 1A. The step coverage can be defined as the ratio between the thickness of the deposited layer at the bottom of the high aspect ratio feature (e.g., the trenches 151) to the thickness of the deposited layer at the top of the features separating the high aspect ratio features (e.g., the dividing structures 154). Thus, in FIG. 1B the step coverage is defined as the ratio of the thickness 167 at the bottom 152 of the trench 151 to the ratio of the thickness 166 at the top of the dividing structures 154. In some embodiments, generating a plasma with pulsed RF power as described in more detail below can achieve step coverages of greater than 70% for high aspect ratio features (e.g., the trenches 151 and dividing structures 154) having an aspect up to or greater than 15:1.

The dividing structures 154 can be phase change memory cell units including electrodes, one or more vias, a phase change memory layer, and other features. In some embodiments, the phase change memory layer can be a chalcogenide material, such as germanium antimony telluride (GST). Thermal engineering is part of developing the next generation of non-volatile phase change memory devices. Phase change materials, such as GST, exist in either an amorphous or crystalline phase, and these phases can be rapidly and repeatedly switched for memory cell operation. The phase switching can be controlled by heating the phase change material (e.g., GST) via optical pulses or electrical (Joule) heating. However, higher temperatures (e.g., >300° C.) can have a detrimental effect on the stability of the phase change materials. The thermal stability of GST is mainly governed by the stoichiometry of the GST, for example GeₓSb_{y}Te_{z}, which decreases with increasing temperature. This decrease in the stoichiometry leads to a corresponding decrease in the set and reset resistance and resistance margin for the memory cells resulting in poor device functionality and performance. More specifically, PECVD of SiN barrier layers over GST phase change memory cells at temperatures higher than 300° C. will cause severe damage to the GST phase change memory cells.

The dielectric layer 161 of FIG. 1E3 is formed using a method of PECVD that applies a pulsed RF power to generate the plasma of the deposition material that forms the dielectric layer 161. This pulsed RF power increases the proportion of radicals in the plasma relative to the amount of ions in the plasma, which slows the deposition rate and allows a more uniform deposition to occur across the deposition surfaces of the high aspect ratio structures.

Upper portions 164 of the dielectric layer 161 are noticeably thinner than the corresponding upper portions 64 of the dielectric layer 61 of FIG. 1A, and the upper portions 164 include little to no overhang 165 relative to the substantial overhang 65 present in the dielectric layer 61 of FIG. 1A. Furthermore, sidewall portions 163 of the dielectric layer 161 have a substantially uniform thickness from the bottom 152 of the trench 151 to the top of the dividing structures 154 when compared to the dielectric layer 61 of FIG. 1A, which included the sidewall portions 63 which were substantially thicker in the upper portions relative to the lower portions. Additionally, bottom portions 162 of the dielectric layer 161 have a thickness 167 that is substantially uniform with the thickness of the sidewall portions 163.

FIG. 1C is a close-up of a section of the dielectric layer 161 shown in FIG. 1B, according to one embodiment. In some embodiments, the dielectric layer 161 can include a first portion 161A deposited on the surfaces of the high aspect ratio structures, such as the sidewalls 153 of the trenches 151, and a second portion 161B deposited on the first portion 161A. The first portion 161A and the second portion 161B can each be formed of a dielectric material, such as silicon nitride. Furthermore, each portion 161A, 161B can be formed using the pulsed PECVD method introduced above and described in more detail below. Before forming the second portion 161B, a plasma treatment can be performed on the first portion 161A. For example, one or more treatment gases, such as nitrogen and an inert gas (e.g., helium or argon) can be supplied to a process volume of a plasma chamber. A plasma can then be generated from the supplied gases using a continuous capacitively coupled plasma (CCP) or an inductively coupled plasma. The plasma treatment helps to increase the density of the deposited film by removing excess hydrogen from the film. The increased density can also make the deposited film a hermetic barrier that is highly resistant to ingress by moisture and/or oxygen enabling the deposited layer to withstand steam annealing at temperatures up to 550° C. without any steam penetration into the bulk of the deposited layer. These improvements to the deposited layer from this plasma treatment also enable the film to better withstand the rigors of subsequent dry chemical etching and patterning operations during integration. In some embodiments, the dielectric layer 161 can include more than two portions, such as three or more portions, and a plasma treatment can be performed between forming each portion.

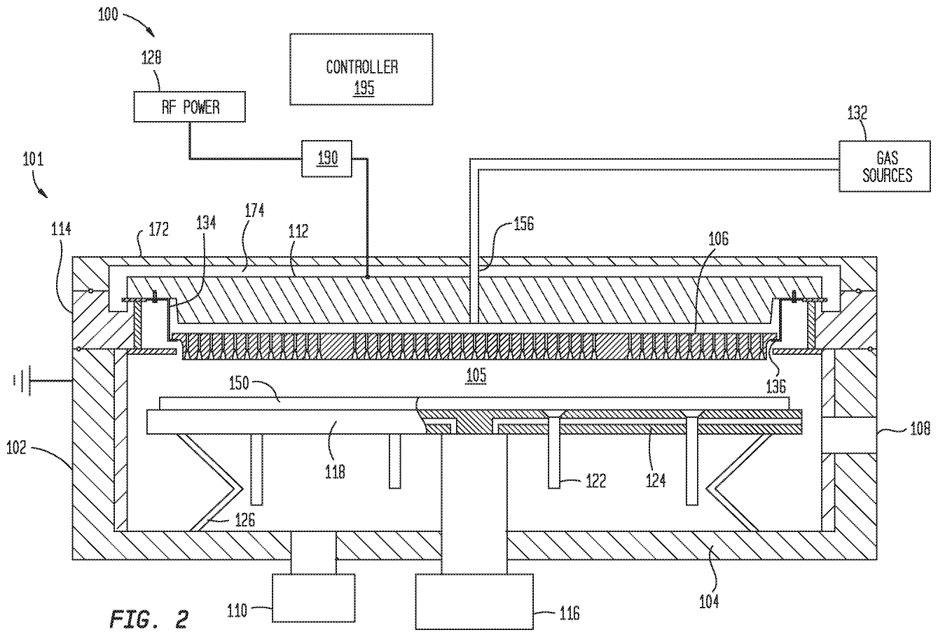

FIG. 2 is a cross sectional view of a PECVD apparatus 100 that can be used to form the dielectric layer 161 of FIG. 1B, according to one embodiment. The apparatus 100 includes a plasma chamber 101 in which one or more layers can be processed (e.g., deposited) on a semiconductor device, such as the semiconductor device 150 of FIG. 1B. The plasma chamber 101 generally includes walls 102, a bottom 104, and a showerhead 106 which together enclose a process volume 105. A substrate support 118 is disposed within the process volume 105. The process volume 105 is accessed through a slit valve opening 108 such that the substrate 120 may be transferred in and out of the plasma chamber 101. The substrate support 118 may be coupled to an actuator 116 to raise and lower the substrate support 118. Lift pins 122 are moveably disposed through the substrate support 118 to move a substrate to and from a substrate receiving surface of the substrate support 118. The substrate support 118 may also include heating and/or cooling elements 124 to maintain the substrate support 118 at a desired temperature. The substrate support 118 may also include RF return straps 126 to provide an RF return path at the periphery of the substrate support 118 to the chamber bottom 104 or walls 102, which can be connected to an electrical ground.

The showerhead 106 is coupled to a backing plate 112. A plurality of gas sources 132 are coupled to the backing plate 112 through a gas conduit 156 to provide gas through gas passages in the showerhead 106 to the process volume 105 between the showerhead 106 and the substrate 120. The gas sources can include sources for the precursors used for the deposition of the dielectric layer 161. For example, in some embodiments in which the dielectric layer 161 is a dielectric (e.g., SiN or SiON), the gas sources 132 can include a silicon source and a nitrogen source. The silicon gas sources for the formation of SiN can include, for example, silane, trisilylamine, disilylamine, silylamine, tridisilylamine, aminodisilylamine etc. The silicon sources for SiCN can include, for example, trisilylamine, mono, di, tri or tetra methyl silane, (Dimethylamino)trimethylsilane, (Dimethylamino)triethylsilane, Hexamethylcyclotrisilazane, or N,N′-disilyltrisilazane. In some embodiments, more than one silicon source can be used included, such as two or more of silane, trisilylamine, and N,N′-disilyltrisilazane. It has been found that using silicon sources with higher molecular weights relative to the molecular weight of silane, such as trisilylamine and N,N′-disilyltrisilazane , can further increase the concentration of radicals relative to the concentration of ions in a plasma as more energy is needed to create an ion of a molecule with a higher molecular weight relative to a molecule with a lower molecular weight. The nitrogen gas sources can include, for example, ammonia and nitrogen. In some embodiments, more than one nitrogen source can be included, such as a nitrogen gas source and an ammonia gas source. Gas sources for the treatment gas can include, for example, nitrogen with an inert gas, such as helium or argon.

A vacuum pump 110 is coupled to the plasma chamber 101 to control the process volume at a desired pressure. The pressure of the process volume during deposition of the dielectric layer 161 can be controlled from about 4 Torr to about 60 Torr, such as from about 8 Torr to about 30 Torr. Higher pressures can be associated with increasing the penetration of the plasma reactants to deeper locations in the high aspect ratio structures, such as to the bottom 152 of the trenches 151 shown in FIG. 1B,

An RF power source 128 is coupled through a match network 190 to the backing plate 112 and/or directly to the showerhead 106 to provide RF power to the showerhead 106. The RF power creates an electric field between the showerhead 106 and the substrate support 118 so that a plasma may be generated from the gases disposed between the showerhead 106 and the substrate support 118 to deposit the dielectric layer 161 or treat the first portion 161A of the dielectric layer 161 as described above in reference to FIGS. 1B and 1C. The substrate support 118 may be connected to an electrical ground. Various frequencies may be used, such as a frequency between about 0.3 MHz and about 200 MHz. In one embodiment, the RF current is provided at a frequency from about 12.88 MHz to about 14.24 MHz, such as 13.56 MHz. In another embodiment, the RF current is provided at a frequency from about 39 MHz to about 41 MHz, such as 40 MHz.

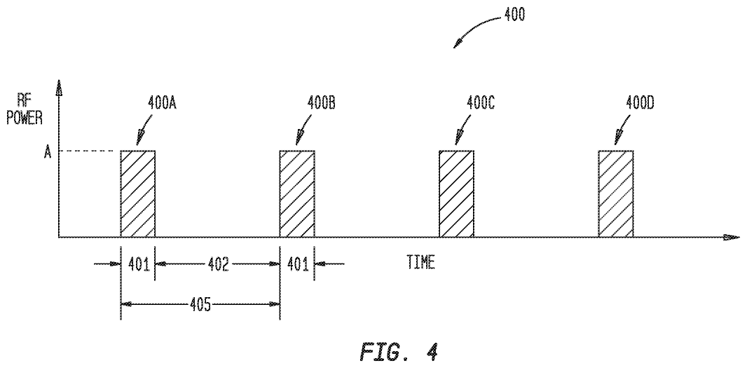

Instead of applying continuous RF power during the deposition of the dielectric layer 161, the RF power can be pulsed to increase the ratio of radicals produced relative to ions produced in the plasma, so that a layer having a higher degree of thickness uniformity is deposited. FIG. 4 illustrates a pulse train 400 that includes a plurality of pulses 400A-400D that have an instantaneous RF power magnitude “A” which can be used during one or more of the processes described herein. Each pulse can include a first period 401 during which the RF power is energized (i.e., RF power is provided at a desired frequency (e.g., 0.3 MHz-200 MHz) during the first period 401), and a second period 402 during which the RF power is not energized. For example, the pulsed RF power can operate with a duty cycle from about 5% to about 60%, for example from about 10% to about 50%, such as from about 20% to about 25% within the total period 405 (or T) of each pulse. The lower duty cycles (e.g., duty cycles from 5% to 25%) can further reduce the average concentration of ions in the plasma during the deposition because there is less time in which RF power can excite electrons from a molecule to create the ions while still providing enough RF power to create radicals in the plasma. In addition, the concentration of ions depletes faster than the concentration of radicals. Thus, having a pulse train having a longer duration between pulses increases the concentration of radicals relative to the concentration of ions over an extended period of time (e.g., a period of time that includes multiple pulses), when compared to a pulse train that has a shorter duration between pulses.

The plurality of pulses within the pulse train 400 can operate at a frequency (1/T) from about 1 kHz to about 100 kHz, such as from about 5 kHz to about 50 kHz. In some embodiments, the total period of a pulse (i.e., period 405) can be from about 10 μs to about 200 μs, such as from about 25 μs to about 100 μs. For example, in one embodiment a pulse having a total period of 100 μs (i.e., period 405) and a duty cycle of 20% includes energizing the RF power for 20 μs (i.e., first period 401) and de-energizing the RF power for 80 μs (second period 402) before starting the next pulse. In another embodiment, a pulse having total period of 25 μs and a duty cycle of 20% includes energizing the RF power for 5 μs and de-energizing the RF power for 20 μs before starting the next pulse. The magnitude of the RF power applied during the first period 401 can be from about 1 W to about 1000 W, such as from about 1 W to about 200 W, or even from about 10 W to about 100 W. In some configurations, the magnitude of an RF power density that is applied to a substrate during the pulsing process is from about 14 W/m² to about 14,000 W/m², such as from about 140 W′/m² to about 1,400 W/m². Higher pressures can be associated with increasing the penetration of the plasma reactants to deeper locations in the high aspect ratio structures, such as to the bottom 152 of the trenches 151 shown in FIG. 1B, which when combined with an RF pulse having the duty cycles (e.g., a duty cycle <25%, such as between 10% and 20%) described above can lead to a more conformal deposition relative to depositions carried out at lower pressures or with continuous RF power.

It has been found that a lower duty cycle for the RF pulse produces a lower ratio of ions relative to radicals in the plasma as compared to higher duty cycles, which lowers the deposition rate, but will help improve the thickness uniformity of layers deposited on high aspect ratio structures, such as the dielectric layer 161 of FIG. 1B, Furthermore, the duty cycle of a pulse train can be further reduced as the aspect ratio of the features of device increase. For example, a duty cycle of 50% may be appropriate for depositing a dielectric layer on a trench having an aspect ratio of 4:1 while a duty cycle of 10% may be appropriate for a trench having an aspect ratio of 15:1.

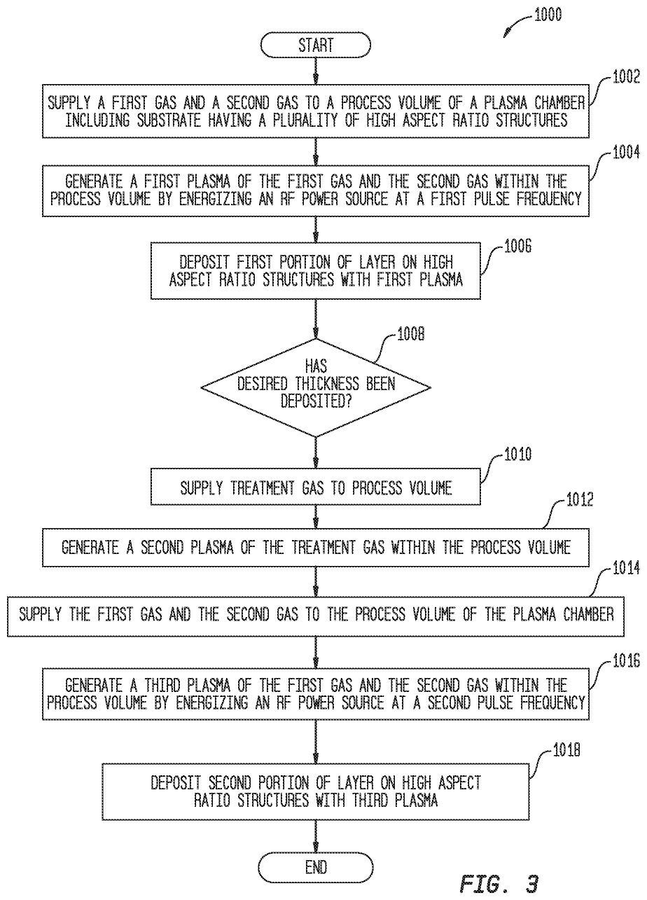

Separately, as discussed further below, a continuous RF power can be applied to the showerhead 106 when treatment gases (e.g., N₂ and He) are supplied to the process volume 105 of the plasma chamber 101, for example as discussed during block 1010 of FIG. 3 below, The treatment gases can be used to increase the density of the deposited film.

The showerhead 106 may additionally be coupled to the backing plate 112 by showerhead suspension 134. In one embodiment, the showerhead suspension 134 is a flexible metal skirt. The showerhead suspension 134 may have a lip 136 upon which the showerhead 106 may rest. The backing plate 112 may rest on an upper surface of a ledge 114 coupled with the chamber walls 102 to seal the plasma chamber 101. A chamber lid 172 may be coupled with the chamber walls 102 and spaced from the backing plate 112 by area 174. In one embodiment, the area 174 may be an open space (e.g., a gap between the chamber walls and the backing plate 112). In another embodiment, the area 174 may be an electrically insulating material. The chamber lid 172 may have an opening therethrough to permit the gas feed conduit 156 to supply processing gas to the plasma chamber 101.

The PECVD apparatus 100 further includes a system controller 195. The system controller 195 is used to control operation of the processes executed with PECVD apparatus 100 including the delivery of the pulsed and continuous RF power to the showerhead 106 from the RF power source 128 during the deposition of the dielectric layer 161 and treatment of the first portion 161A of the dielectric layer 161 as described above in reference to FIGS. 1B and 1C. The system controller 195 is generally designed to facilitate the control and automation of the plasma chamber 101 and may communicate to the various sensors, actuators, and other equipment associated with the plasma chamber 101 through wired or wireless connections. The system controller 195 typically includes a central processing unit (CPU) (not shown), memory (not shown), and support circuits (or I/O) (not shown).

The CPU may be one of any form of computer processors that are used in industrial settings for controlling various system functions, substrate movement, chamber processes, and control support hardware (e.g., sensors, internal and external robots, motors, gas flow control, etc.), and monitor the processes performed in the system (e.g., RF power measurements, chamber process time, I/O signals, etc.). The memory is connected to the CPU, and may be one or more of a readily available memory, such as random access memory (RAM), read only memory (ROM), floppy disk, hard disk, or any other form of digital storage, local or remote. Software instructions and data can be coded and stored within the memory for instructing the CPU.

The support circuits are also connected to the CPU for supporting the processor in a conventional manner. The support circuits may include cache, power supplies, clock circuits, input/output circuitry, subsystems, and the like. A program (or computer instructions) readable by the system controller 195 determines which tasks are performable on a substrate in the plasma chamber 101. Preferably, the program is software readable by the system controller 195 that includes code to perform tasks relating to monitoring, execution and control of the movement, support, and/or positioning of a substrate along with the various process recipe tasks (e.g., inspection operations, processing environment controls) and various chamber process recipe operations being performed in the plasma chamber 101.

FIG. 3 is a process flow diagram of a method 1000 of forming the dielectric layer 161 on the substrate 40 of FIG. 1B using the PECVD apparatus 100 of FIG. 2, according to one embodiment. Referring to FIGS. 1B, 1C, 2, and 3, the method 1000 is described. In one embodiment, the method 1000 can be applied to encapsulate phase change memory cell units with a dielectric layer having good step coverage, such as step coverage greater than 60% or even 80%. In other embodiments, the method 1000 can be applied more generally to deposit a conformal layer having good step coverage on the surfaces of high aspect ratio features, such as features having an aspect ratio greater than 4:1.

At block 1002, a first gas and a second gas are supplied to the process volume 105 of the plasma chamber 101 when the substrate 40 including the high aspect ratio structures (i.e., trenches 151) is disposed on the substrate support 118. In one embodiment, the first gas can be a silicon source and the second gas can be a nitrogen source. In some embodiments, more than one silicon source can be used included, such as two or more of silane, trisilylamine, and N,N′-disilyltrisilazane. It has been found that using silicon sources with higher molecular weights relative to the molecular weight of silane, such as trisilylamine and N,N′-disilyltrisilazane, can further increase the concentration of radicals relative to the concentration of ions in a plasma as more energy is needed to create an ion of a molecule with a higher molecular weight relative to a molecule with a lower molecular weight. Thus, using silicon sources with higher molecular weights leads to a high concentration of radicals in the plasma, which in turn leads to a more conformal deposition. The nitrogen gas sources can include, for example, ammonia and nitrogen. In some embodiments, more than one nitrogen source can be included, such as a nitrogen gas source and an ammonia gas source.

At block 1004, a first plasma of the first gas and the second gas is generated within the process volume 105 by energizing the RF power source 128 coupled to the plasma chamber 101 at a first pulse frequency. The first pulse frequency can be from about 1 kHz to about 100 kHz, such as from about 5 kHz to about 50 kHz. The first pulse frequency can have a duty cycle from about 5% to about 60%, such as from about 10% to about 50%, such as from about 20% to about 25%. In some embodiments, the total period of a pulse can be from about 10 μs to about 200 μs, such as from about 25 μs to about 100 μs. At block 1006, the first portion 161A of the dielectric layer 161 is deposited on the high aspect ratio structure (i.e., trenches 151) using the first plasma. At block 1004 the first plasma is generated at a pressure from about 1 Tarr to about 60 Torr, such as from about 8 Tarr to about 30 Torr, such as about 16 Torr. At block 1004, the temperature in the process volume 105 can be less than 300° C., such as from about 200° C. to about 295° C., such as from about 250° C. to about 280° C.

At block 1008, the controller 195 is used to determine when a target thickness of the first portion 161A of the dielectric layer 161 has been deposited. In one embodiment, the deposition rate of the first portion 161A of the dielectric layer 161 is known and the deposition is stopped after a timer expires, where the duration of the timer is determined based on the target thickness and known deposition rate. In another embodiment, the thickness of the first portion 161A is monitored as the first portion 161A is deposited, for example using an in-situ metrology assembly, and the controller stops the deposition when the monitored thickness reaches the target thickness. In some embodiments in which the dielectric layer 161 is deposited to encapsulate a memory cell, the target thickness of the first portion 161A can be from about 10 Å to about 50 Å, such as from about 20 Å to about 30 Å.

At block 1010, gases (e.g., N₂ and He) for a plasma treatment can be supplied to the process volume 105 of the plasma chamber 101. The treatment gases can be supplied to the process volume 105 in the absence of the first gas and the second gas. However, in some embodiments, the nitrogen source and the treatment gas can be the same gas, such as when both gases are N₂. At block 1012 a second plasma of the treatment gases is generated at a pressure from about 1 Torr to about 60 Torr, such as about from 8 Torr to about 30 Torr. The second plasma can be generated using a continuous plasma for predetermined about of time. These treatment gases can be used to increase the density of the deposited film. During this plasma treatment, hydrogen (residing in the film as Si—H and N—H) is removed from the deposited film, which leads to film densification. Furthermore, during the plasma treatment more nitrogen atoms become incorporated in the film with the formation of additional Si—N bonds leading to improved silicon nitride film quality. In one embodiment, the ratio of helium to nitrogen supplied during the plasma treatment can be from about 2:1 to about 10:1, such as about 6:1.

At block 1014, the first gas (e.g., the silicon source) and the second gas (e.g., the nitrogen source (e.g., NH₃ and N₂)) are supplied to the process volume 105 of the plasma chamber 101 after generation of the second plasma. At block 1016, a third plasma of the first gas and the second gas is generated within the process volume 105 by energizing an RF power source 128 coupled to the plasma chamber 101 at a second pulse frequency. The second pulse frequency can be from about 1 kHz to about 100 kHz, such as from about 5 kHz to about 50 kHz. The second pulse frequency can have a duty cycle from about 5% to about 60%, such as from about 10% to about 50%, such as from about 20% to about 25%. In some embodiments, the total period of a pulse can be from about 10 μs to about 200 μs, such as from about 25 μs to about 100 μs. At block 1016, the second portion 161B of the dielectric layer 161 is deposited on the first portion 161A of the dielectric layer 161 using the third plasma.

In some embodiments, the characteristics of the second pulse frequency (e.g., pulse frequency, duty cycle, RF power magnitude and frequency, and total period of the pulse) can be identical to the characteristics of the first pulse frequency. However, in other embodiments, the characteristics of the second pulse frequency (e.g., pulse frequency, duty cycle, RF power magnitude and frequency, and total period of the pulse) can be substantially different than the first pulse frequency. For example, the duty cycle of the second pulse frequency can be substantially increased (e.g., an increase of 20% or more) for the second pulse frequency relative to the duty cycle of the first pulse frequency. The higher duty cycle can result in a higher concentration of ions in the plasma, which can be used to increase the density of the deposited film, which improves the barrier properties of deposited film (e.g., silicon nitride). For example, the lower duty cycle of the first pulse frequency can be used to ensure sufficient deposition at the bottom the high aspect ratio features while the higher duty cycle of the second pulse frequency can be used to increase the density of the deposited film. Furthermore, other characteristics of the second pulse frequency can be modified relative to the first pulse frequency, such as modifying the frequency of the RF signal that is applied during the pulse, such as switching from a 13.56 MHz frequency during the first pulse frequency to a 40 MHz frequency during the second pulse frequency allowing for different properties of the deposited film to be tuned, such as the compressive or tensile stress present in the deposited film. For example, the first pulse frequency can be controlled to ensure sufficient deposition at the bottom the high aspect ratio features while the second pulse frequency can be used to modify the compressive or tensile stress of the deposited film.

While the foregoing is directed to embodiments of the present disclosure, other and further embodiments of the disclosure may be devised without departing from the basic scope thereof, and the scope thereof is determined by the claims that follow.

1. A method of forming a layer on a substrate, comprising:
supplying a first gas and a second gas to a process volume of a plasma chamber, wherein a substrate is disposed on a substrate support in the process volume and the substrate includes a plurality of high aspect ratio structures having an aspect ratio of at least 4:1; and
depositing a first portion of a layer by generating a first plasma of the first gas and the second gas within the process volume by energizing an RF power source coupled to the plasma chamber at a first pulse frequency, wherein
the first pulse frequency is from about 1 kHz to about 100 kHz, and
the first pulse frequency has a duty cycle from about 10% to about 50%.

2. The method of claim 1, wherein the plurality of high aspect ratio structures have an aspect ratio of at least 15:1.

3. The method of claim 1, wherein the first portion of the layer is a dielectric material comprising silicon and a temperature of the process volume during the depositing the first portion is less than 300° C.

4. The method of claim 1, wherein a pressure in the process volume during the depositing the first portion is from about 8 Torr to about 30 Torr.

5. The method of claim 1, wherein the first pulse frequency has a duty cycle from about 20% to about 25%.

6. The method of claim 1, further comprising
supplying one or more treatment gases to the process volume in an absence of the first gas and the second gas after depositing a thickness of at least 20 Å of the first portion of the layer on the substrate with the first plasma, wherein the one or more treatment gases comprises nitrogen and helium; and
generating a second plasma of the treatment gas at a pressure from about 8 Torr to about 30 Torr.

7. The method of claim 6, further comprising
supplying the first gas and the second gas to the process volume of the plasma chamber after generating the second plasma; and
depositing a second portion of the layer by generating a third plasma of the first gas and the second gas within the process volume after generating the second plasma by energizing the RF power source coupled to the plasma chamber at a second pulse frequency, wherein
the second pulse frequency is from about 1 kHz to about 100 kHz, and
the second pulse frequency has a duty cycle from about 10% to about 50%.

8. The method of claim 7, wherein the second pulse frequency is the same as the first pulse frequency.

9. A method of forming a dielectric layer on a substrate, comprising:
supplying a first gas comprising silicon and a second gas comprising nitrogen to a process volume of a plasma chamber, wherein a substrate is disposed on a substrate support in the process volume and the substrate includes a plurality of high aspect ratio structures having an aspect ratio of at least 4:1; and
depositing a first portion of a dielectric layer by generating a first plasma of the first gas and the second gas within the process volume by energizing an RF power source coupled to the plasma chamber at a first pulse frequency, wherein
the first pulse frequency is from about 1 kHz to about 100 kHz, and
the first pulse frequency has a duty cycle from about 10% to about 50%.

10. The method of claim 9, wherein the first gas comprising silicon includes one or more gases having a molecular weight greater than silane.

11. The method of claim 9, wherein
the first portion of the dielectric layer is silicon nitride and a temperature of the process volume during the depositing the first portion is less than 300° C.

12. The method of claim 9, further comprising
supplying one or more treatment gases to the process volume in an absence of the first gas and the second gas after depositing a thickness of at least 20 Å of the first portion of the dielectric layer on the substrate with the first plasma; and
generating a second plasma of the one or more treatment gases at a pressure from about 8 Torr to about 30 Torr.

13. The method of claim 12, further comprising
supplying the first gas and the second gas to the process volume of the plasma chamber after generating the second plasma; and
depositing a second portion of the dielectric layer by generating a third plasma of the first gas and the second gas within the process volume after generating the second plasma by energizing the RF power source coupled to the plasma chamber at a second pulse frequency, wherein
the second pulse frequency is from about 1 kHz to about 100 kHz, and
the second pulse frequency has a duty cycle from about 10% to about 50%.

14. A method of encapsulating a phase change memory cell unit with a dielectric layer, comprising:
supplying a first gas comprising silicon and a second gas comprising nitrogen to a process volume of a plasma chamber, wherein a substrate is disposed on a substrate support in the process volume and the substrate includes a plurality of phase change memory cell units separated by trenches that have an aspect ratio of at least 4:1; and
depositing a first portion of a dielectric layer by generating a first plasma of the first gas and the second gas within the process volume by energizing an RF power source coupled to the plasma chamber at a first pulse frequency, wherein
the first pulse frequency is from about 1 kHz to about 100 kHz,
the first pulse frequency has a duty cycle from about 10% to about 50%,
a temperature of the process volume during the depositing the first portion is less than 300° C., and
a pressure in the process volume during the depositing the first portion is from about 8 Torr to about 30 Torr.

15. The method of claim 14, further comprising
supplying one or more treatment gases to the process volume in an absence of the first gas and the second gas after depositing a thickness of at least 20 Å of the first portion of the dielectric layer on the substrate with the first plasma, wherein the one or more treatment gases comprise nitrogen and helium;
generating a second plasma of the one or more treatment gases at a pressure from about 8 Torr to about 30 Torr;
supplying the first gas and the second gas to the process volume of the plasma chamber after generating the second plasma; and
depositing a second portion of the dielectric layer by generating a third plasma of the first gas and the second gas within the process volume after generating the second plasma by energizing the RF power source coupled to the plasma chamber at a second pulse frequency, wherein
the second pulse frequency is from about 1 kHz to about 100 kHz, and
the second pulse frequency has a duty cycle from about 10% to about 50%.

16. The method of claim 6, wherein the one or more treatment gases comprises nitrogen and helium.

17. The method of claim 9, wherein a pressure in the process volume during the depositing the first portion is from about 8 Torr to about 30 Torr.

18. The method of claim 9, wherein the first pulse frequency has a duty cycle from about 20% to about 25%.

19. The method of claim 12, wherein the one or more treatment gases comprises nitrogen and helium and the first gas comprising silicon includes trisilylamine and N,N′-disilyltrisilazane.

20. The method of claim 13, wherein the second pulse frequency is the same as the first pulse frequency.
